(19) United States
(12) Patent Application Publication
(10) Pub. No.: US 2023/0307226 A1
(43) Pub. Date: Sep. 28, 2023

(54) METHOD OF DEPOSITING THIN FILM AND METHOD OF MANUFACTURING MEMORY DEVICE INCLUDING THE SAME

(71) Applicant: EGTM Co., Ltd., Suwon-si (KR)

(72) Inventors: Ha Na KIM, Suwon-si Gyeonggi-do (KR); Ju Hwan ` JEONG, Suwon-si (KR); Kyu Ho CHO, Suwon-si (KR); Jae Min KIM, Suwon-si (KR); Duck Hyeon SEO, Suwon-si (KR); Ji Yeon HAN, Suwon-si (KR); Hyun Ju JUNG, Suwon-si (KR)

(73) Assignee: EGTM Co., Ltd., Suwon-si (KR)

(21) Appl. No.: 18/314,842

(22) Filed: May 10, 2023

(30) Foreign Application Priority Data
May 10, 2020 (KR) 10-2022-0057133
Apr. 14, 2023 (KR) 10-2023-0049570

(51) Int. Cl. H01L 21/02; C23C 16/40; C23C 16/455

(52) U.S. Cl. CPC H01L 21/02164; C23C 16/403; C23C 16/45553; C23C 16/45527

(57) ABSTRACT

Disclosed is a method of depositing thin film, the method comprising: supplying an adduct precursor to the inside of a chamber in which a substrate including at least one gap feature is placed so that the adduct precursor is adsorbed to the substrate; purging the interior of the chamber; and supplying a reaction material to the inside of the chamber so that the reaction material reacts with the adduct precursor to form the thin film and fill the gap feature, wherein the adduct precursor is formed by mixing 1 to 5 moles of a compound and 1 to 5 moles of a metal compound.

### TECHNICAL FIELD

The present invention relates to a method of depositing thin film and method of manufacturing memory device, and more particularly, a method of depositing thin film using an adduct precursor and method of manufacturing memory device including the same.

### BACKGROUND

Atomic layer deposition (ALD) is used as a process for filling gap features such as trenches formed on a substrate. Since atomic layer deposition uses a surface reaction, it is possible to form a uniform thickness when filling gap features using atomic layer deposition, thereby minimizing the formation of voids.

However, as the gap feature changes to a high aspect ratio, a case occurs where the size of the gap entrance is smaller than the internal size of the gap. Also, as the gap entrance narrows, it causes a hindrance to sufficient diffusion of the reactants into the lower portions of the features having high aspect ratio.

Insufficient diffusion also results in a deposition profile in which the coverage decreases on the sidewall of the feature as the depth increases, and defects such as voids or seams may occur even when atomic layer deposition is used, resulting in the formation of membranes with porosity greater than desired.

In addition, ALD for gap filling may be repeated hundreds of times to achieve a target film thickness, which may be disadvantageous in terms of throughput. Therefore, in the case of the gap feature having a high aspect ratio, it is advantageous to have a higher growth rate at the bottom than at the top, and various growth suppression technologies are being developed for this purpose.

An object of the present invention is to provide a method of depositing thin film capable of minimizing the occurrence of defects and securing a high yield, and a method of manufacturing a memory device including the same.

Other objects of the present invention will become more apparent from the following detailed description.

### SUMMARY

Disclosed is a method of depositing thin film, the method comprising: supplying an adduct precursor to the inside of a chamber in which a substrate including at least one gap feature is placed so that the adduct precursor is adsorbed to the substrate; purging the interior of the chamber; and supplying a reaction material to the inside of the chamber so that the reaction material reacts with the adduct precursor to form the thin film and fill the gap feature, wherein the adduct precursor is formed by mixing 1 to 5 moles of a compound represented by the following Chemical Formula 1 or following Chemical Formula 2 and 1 to 5 moles of a metal compound.

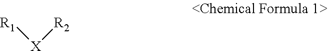

wherein X is O or S, and R1 or R2 is each independently selected from an alkyl group having 1 to 8 carbon atoms, a cycloalkyl group having 3 to 6 carbon atoms, and an aryl group having 6 to 12 carbon atoms.

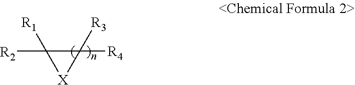

wherein X is O or S, n is 1 to 5, and R1 to R4 are each independently selected from a hydrogen atom, an alkyl group having 1 to 5 carbon atoms, a cycloalkyl group having 3 to 6 carbon atoms, and an aryl group having 6 to 12 carbon atoms.

The adduct precursor may be formed by mixing ethyl methyl sulfide or ethyl propyl ether or tetrahydrofuran with the metal compound.

The metal compound may have at least one of group 4 elements including Zr, Hf, and Ti as a central element.

The metal compound may be represented by the following Chemical Formula 3.

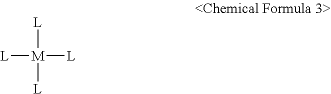

wherein M is selected from metal elements belonging to group 4 on the periodic table,

each L is the same as or different from each other, and is selected from a hydrogen atom, a linear/branched/cyclic alkyl group having 1 to 10 carbon atoms, an alkoxy group having 1 to 5 carbon atoms, an amino group having 1 to 5 carbon atoms, a dialkylamino group having 1 to 5 carbon atoms, an aryl group having 6 to 12 carbon atoms, an aralkyl group having 7 to 13 carbon atoms, and a halogen element.

The metal compound may be represented by the following Chemical Formula 4.

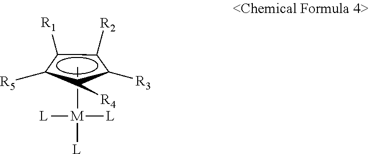

wherein M is selected from metal elements belonging to group 4 on the periodic table,

R1, R2, R3, R4, and R5 are each independently selected from a hydrogen atom, a linear/branched/cyclic alkyl group having 1 to 5 carbon atoms, an alkoxy group having 1 to 5 carbon atoms, and a phenyl group having 6 to 12 carbon atoms,

each L is the same as or different from each other, and is selected from a hydrogen atom, a linear/branched/cyclic alkyl group having 1 to 10 carbon atoms, an alkoxy group having 1 to 5 carbon atoms, an amino group having 1 to 5 carbon atoms, a dialkylamino group having 1 to 5 carbon atoms, an aryl group having 6 to 12 carbon atoms, and an aralkyl group having 7 to 13 carbon atoms,

when L is a dialkylamino group, being connected to each other to form a cyclic amine group having 3 to 10 carbon atoms.

The metal compound may have at least one of group 5 elements including Nb and Ta as a central element.

The metal compound may be represented by the following Chemical Formula 5 or the following Chemical Formula 6.

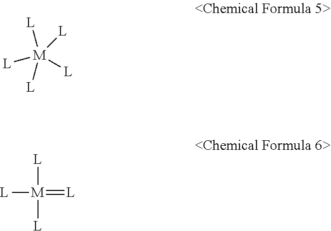

wherein M is selected from metal elements belonging to group 5 on the periodic table,

each L is the same as or different from each other, and is selected from a hydrogen atom, a linear/branched/cyclic alkyl group having 1 to 10 carbon atoms, an alkoxy group having 1 to 5 carbon atoms, an amino group having 1 to 5 carbon atoms, a dialkylamino group having 1 to 5 carbon atoms, an aryl group having 6 to 12 carbon atoms, an aralkyl group having 7 to 13 carbon atoms, and a halogen element.

The metal compound may be represented by the following Chemical Formula 7.

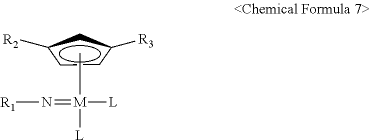

wherein M is selected from metal elements belonging to group 5 on the periodic table,

R1, R2, and R3 are each independently selected from a hydrogen atom and a linear/branched/cyclic alkyl group having 1 to 5 carbon atoms,

each L is the same as or different from each other, and is selected from a hydrogen atom, a linear/branched/cyclic alkyl group having 1 to 10 carbon atoms, an alkoxy group having 1 to 5 carbon atoms, an amino group having 1 to 5 carbon atoms, a dialkylamino group having 1 to 5 carbon atoms, an aryl group having 6 to 12 carbon atoms, an aralkyl group having 7 to 13 carbon atoms, and a halogen element.

The metal compound has at least one of group 6 elements including W and Mo as a central element.

The metal compound is represented by the following Chemical Formula 8 or the following Chemical Formula 9.

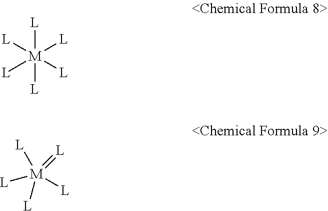

wherein M is selected from metal elements belonging to group 6 on the periodic table,

each L is the same as or different from each other, and is selected from a hydrogen atom, a linear/branched/cyclic alkyl group having 1 to 10 carbon atoms, an alkoxy group having 1 to 5 carbon atoms, an amino group having 1 to 5 carbon atoms, a dialkylamino group having 1 to 5 carbon atoms, an aryl group having 6 to 12 carbon atoms, an aralkyl group having 7 to 13 carbon atoms, and a halogen element.

The metal compound may have at least one of group 13 elements including Al as a central element.

The metal compound is represented by the following Chemical Formula 10.

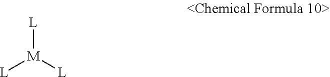

wherein M is selected from metal elements belonging to group 13 on the periodic table,

each L is the same as or different from each other, and is selected from a hydrogen atom, a linear/branched/cyclic alkyl group having 1 to 10 carbon atoms, an alkoxy group having 1 to 5 carbon atoms, an amino group having 1 to 5 carbon atoms, a dialkylamino group having 1 to 5 carbon atoms, an aryl group having 6 to 12 carbon atoms, an aralkyl group having 7 to 13 carbon atoms, and a halogen element.

Disclosed is a method of depositing thin film, the method comprising: supplying an adduct precursor to the inside of a chamber in which a substrate including at least one gap feature is placed so that the adduct precursor is adsorbed to the substrate; purging the interior of the chamber; and supplying a reaction material to the inside of the chamber so that the reaction material reacts with the adduct precursor to form the thin film and fill the gap feature, wherein the adduct precursor is formed by mixing 1 to 5 moles of a compound represented by the following Chemical Formula 1 or following Chemical Formula 2 and 1 to 5 moles of a non-metal compound.

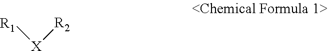

wherein X is O or S, and R1 or R2 is each independently selected from an alkyl group having 1 to 8 carbon atoms, a cycloalkyl group having 3 to 6 carbon atoms, and an aryl group having 6 to 12 carbon atoms.

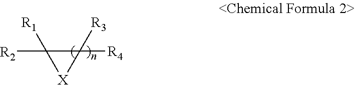

wherein X is O or S, n is 1 to 5, and R1 to R4 are each independently selected from a hydrogen atom, an alkyl group having 1 to 5 carbon atoms, a cycloalkyl group having 3 to 6 carbon atoms, and an aryl group having 6 to 12 carbon atoms.

The adduct precursor is formed by mixing ethyl methyl sulfide or ethyl propyl ether or tetrahydrofuran with the metal compound.

The non-metal compound has at least one of group 14 elements including Si and Ge as a central element.

The non-metal compound is represented by the following Chemical Formula 11.

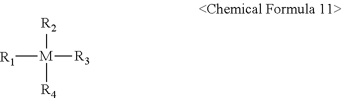

wherein M is one of group 14 elements including Si and Ge,

R1 to R4 are each independently a hydrogen atom, an alkyl group having 1 to 10 carbon atoms, an aryl group having 6 to 12 carbon atoms, an alkylamine group having 1 to 10 carbon atoms, a dialkyl amine group having 1 to 10 carbon atoms, an arylamine group having 6 to 12 carbon atoms, aralkylamine group having 7 to 13 carbon atoms, cyclic amine group having 3 to 10 carbon atoms, heterocyclic amine group having 3 to 10 carbon atoms, heteroarylamine group having 6 to 12 carbon atoms, alkylsilylamine group having 2 to 10 carbon atoms It is selected from a silylamine group, an azide group, and a halogen.

The non-metal compound is represented by the following Chemical Formula 12.

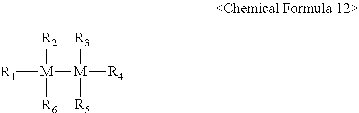

wherein M is one of group 14 elements including Si and Ge,

R1 to R6 are each independently a hydrogen atom, an alkyl group having 1 to 10 carbon atoms, an aryl group having 6 to 12 carbon atoms, an alkylamine group having 1 to 10 carbon atoms, a dialkyl amine group having 1 to 10 carbon atoms, an arylamine group having 6 to 12 carbon atoms, aralkylamine group having 7 to 13 carbon atoms, cyclic amine group having 3 to 10 carbon atoms, heterocyclic amine group having 3 to 10 carbon atoms, heteroarylamine group having 6 to 12 carbon atoms, alkylsilylamine group having 2 to 10 carbon atoms It is selected from a silylamine group, an azide group, and a halogen.

The thin film may be any one of metal oxide, metal nitride, metal sulfide, or metal.

The thin film may be any one of non-metal oxide, non-metal nitride, non-metal sulfide, or non-metal.

The method may proceed at a dissociation temperature or higher of the adduct precursor.

The method may proceed at 50 to 700° C.

Disclosed is a method of manufacturing a volatile memory device, the method comprising the above-mentioned method of forming a thin film.

Disclosed is a method of manufacturing a non-volatile memory device, the method comprising the above-mentioned method of forming a thin film.

### ADVANTAGEOUS EFFECTS

According to the present invention, it is possible to form a Si or metal-containing layer filled upward from the bottom on the gap feature. In addition, even if process conditions are adjusted for each cycle or there is no surface modification such as plasma or chemical modification, different deposition thicknesses of the upper and lower parts can be realized through general ALD. In addition, it is possible to improve electrical characteristics by achieving defect-free gap fill.

### BRIEF DESCRIPTION OF THE DRAWINGS

FIG. 1 is a schematic cross-sectional view of a substrate having gap features.

FIG. 2 is a 1H-NMR graph of the precursor TMA-EMS according to Example 1 of the present invention.

FIGS. 3 and 4 are graphs showing differential scanning calorimetry (DSC) test results and thermogravimetric analysis (TGA) test results for Example 1.

FIG. 5 is a graph showing GPC (Growth Per Cycle) of aluminum oxide films according to Comparative Example 1 and Example 1 of the present invention according to process temperature.

FIG. 6 is a result of confirming step coverage by depositing an aluminum oxide film according to Comparative Example 1 of the present invention on a pattern wafer at a process temperature of 400° C. (aspect ratio 20:1).

FIG. 7 is a result of confirming step coverage by depositing an aluminum oxide film according to Example 1 of the present invention on a pattern wafer at a process temperature of 400° C. (aspect ratio 20:1).

### DETAILED DESCRIPTION

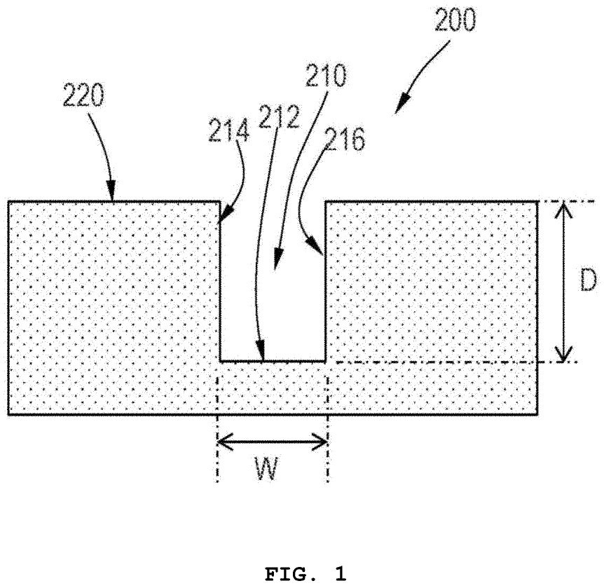

Hereinafter, embodiments of the present invention will be described using FIGS. 1 to 6. The embodiments of the present invention may include various modifications, and the scope of the present invention should not be construed to be limited to the embodiments described below.

The precursor according to an embodiment of the present invention is present as a stable adduct by combining with organic materials at room temperature/pressure, but is dissociated before being adsorbed to the surface of the substrate by thermal energy, collision, etc. in a chamber.

In addition, in the upper part of the gap feature, the reactivity of the precursor decreases due to an increase in size and a blocking effect, thereby reducing the adsorption density. At the lower part of the gap feature, organic matter is dissociated and removed, and metal and non-metal compounds are adsorbed by themselves, thereby increasing the adsorption density. In particular, the deposition thickness is increased to enable bottom-up filling.

In addition, since the GPC is different at the top and bottom according to the depth of the gap feature, defect-free gap fill can be realized even in a structure with a high aspect ratio.

According to an example of the present invention, a method of depositing thin film comprising: supplying an adduct precursor to the inside of a chamber in which a substrate is placed; purging the interior of the chamber; and supplying a reaction material to the inside of the chamber so that the reaction material reacts with the adduct precursor to form the thin film. The adduct precursor is supplied and the thin film is formed at 50 to 700° C.

The substrate has one or more gap features. A gap feature may refer to an opening or cavity disposed between one or more sloped surfaces of a non-planar surface. A gap feature may refer to an opening or cavity disposed between opposing sloped sidewall(s) of two protrusions extending perpendicularly from the surface of a substrate. A gap feature may refer to an opening or cavity disposed between one or more opposing sloped sidewall(s) of a depression extending vertically from the surface of a substrate.

FIG. 1 is a schematic cross-sectional view of a substrate having gap features. At least one gap feature 210 forms an opening in the substrate surface 220. Gap feature 210 extends from substrate surface 220 to depth D to bottom surface 212. Gap feature 210 has a first sidewall 214 and a second sidewall 216 that define a width W of gap feature 210. The open area formed by the sidewalls and the lowermost portion is also referred to as a gap.

The substrate is exposed to the adduct precursor supplied to the interior of the chamber, and the adduct precursor is adsorbed to the gap feature of the substrate.

According to one example of the present invention, the adduct precursor is formed by mixing 1 to 5 moles of a compound represented by the following Chemical Formula 1 or following Chemical Formula 2 and 1 to 5 moles of a metal compound.

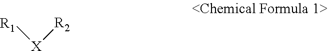

wherein X is O or S, and R1 or R2 is each independently selected from an alkyl group having 1 to 8 carbon atoms, a cycloalkyl group having 3 to 6 carbon atoms, and an aryl group having 6 to 12 carbon atoms.

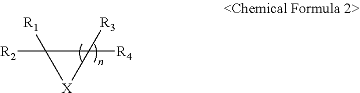

wherein X is O or S, n is 1 to 5, and R1 to R4 are each independently selected from a hydrogen atom, an alkyl group having 1 to 5 carbon atoms, a cycloalkyl group having 3 to 6 carbon atoms, and an aryl group having 6 to 12 carbon atoms.

The adduct precursor may be formed by mixing ethyl methyl sulfide or ethyl propyl ether or tetrahydrofuran with the metal compound.

The metal compound may have at least one of group 4 elements including Zr, Hf, and Ti as a central element.

The metal compound may be represented by the following Chemical Formula 3.

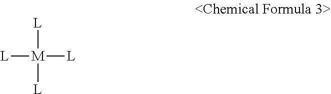

wherein M is selected from metal elements belonging to group 4 on the periodic table,

each L is the same as or different from each other, and is selected from a hydrogen atom, a linear/branched/cyclic alkyl group having 1 to 10 carbon atoms, an alkoxy group having 1 to 5 carbon atoms, an amino group having 1 to 5 carbon atoms, a dialkylamino group having 1 to 5 carbon atoms, an aryl group having 6 to 12 carbon atoms, an aralkyl group having 7 to 13 carbon atoms, and a halogen element.

The metal compound may be represented by the following Chemical Formula 4.

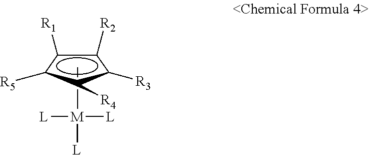

wherein M is selected from metal elements belonging to group 4 on the periodic table,

R1, R2, R3, R4, and R5 are each independently selected from a hydrogen atom, a linear/branched/cyclic alkyl group having 1 to 5 carbon atoms, an alkoxy group having 1 to 5 carbon atoms, and a phenyl group having 6 to 12 carbon atoms,

each L is the same as or different from each other, and is selected from a hydrogen atom, a linear/branched/cyclic alkyl group having 1 to 10 carbon atoms, an alkoxy group having 1 to 5 carbon atoms, an amino group having 1 to 5 carbon atoms, a dialkylamino group having 1 to 5 carbon atoms, an aryl group having 6 to 12 carbon atoms, and an aralkyl group having 7 to 13 carbon atoms,

when L is a dialkylamino group, being connected to each other to form a cyclic amine group having 3 to 10 carbon atoms.

The metal compound may have at least one of group 5 elements including Nb and Ta as a central element.

The metal compound may be represented by the following Chemical Formula 5 or the following Chemical Formula 6.

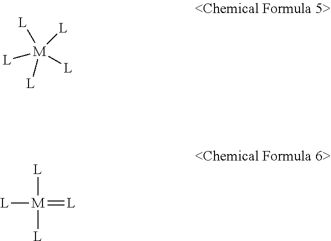

wherein M is selected from metal elements belonging to group 5 on the periodic table,

each L is the same as or different from each other, and is selected from a hydrogen atom, a linear/branched/cyclic alkyl group having 1 to 10 carbon atoms, an alkoxy group having 1 to 5 carbon atoms, an amino group having 1 to 5 carbon atoms, a dialkylamino group having 1 to 5 carbon atoms, an aryl group having 6 to 12 carbon atoms, an aralkyl group having 7 to 13 carbon atoms, and a halogen element.

The metal compound may be represented by the following Chemical Formula 7.

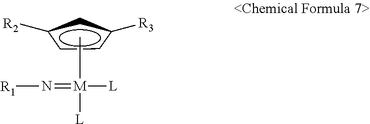

wherein M is selected from metal elements belonging to group 5 on the periodic table,

R1, R2, and R3 are each independently selected from a hydrogen atom and a linear/branched/cyclic alkyl group having 1 to 5 carbon atoms,

each L is the same as or different from each other, and is selected from a hydrogen atom, a linear/branched/cyclic alkyl group having 1 to 10 carbon atoms, an alkoxy group having 1 to 5 carbon atoms, an amino group having 1 to 5 carbon atoms, a dialkylamino group having 1 to 5 carbon atoms, an aryl group having 6 to 12 carbon atoms, an aralkyl group having 7 to 13 carbon atoms, and a halogen element.

The metal compound has at least one of group 6 elements including W and Mo as a central element.

The metal compound is represented by the following Chemical Formula 8 or the following Chemical Formula 9.

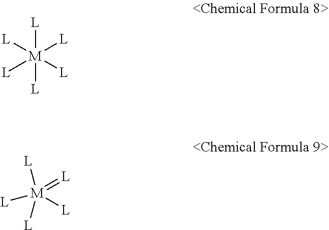

wherein M is selected from metal elements belonging to group 6 on the periodic table,

each L is the same as or different from each other, and is selected from a hydrogen atom, a linear/branched/cyclic alkyl group having 1 to 10 carbon atoms, an alkoxy group having 1 to 5 carbon atoms, an amino group having 1 to 5 carbon atoms, a dialkylamino group having 1 to 5 carbon atoms, an aryl group having 6 to 12 carbon atoms, an aralkyl group having 7 to 13 carbon atoms, and a halogen element.

The metal compound may have at least one of group 13 elements including Al as a central element.

The metal compound is represented by the following Chemical Formula 10.

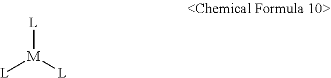

wherein M is selected from metal elements belonging to group 13 on the periodic table,

each L is the same as or different from each other, and is selected from a hydrogen atom, a linear/branched/cyclic alkyl group having 1 to 10 carbon atoms, an alkoxy group having 1 to 5 carbon atoms, an amino group having 1 to 5 carbon atoms, a dialkylamino group having 1 to 5 carbon atoms, an aryl group having 6 to 12 carbon atoms, an aralkyl group having 7 to 13 carbon atoms, and a halogen element.

According to another example of the present invention, the adduct precursor is formed by mixing 1 to 5 moles of a compound represented by the following Chemical Formula 1 or following Chemical Formula 2 and 1 to 5 moles of a non-metal compound.

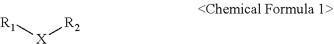

wherein X is O or S, and R1 or R2 is each independently selected from an alkyl group having 1 to 8 carbon atoms, a cycloalkyl group having 3 to 6 carbon atoms, and an aryl group having 6 to 12 carbon atoms.

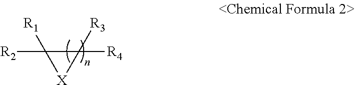

wherein X is O or S, n is 1 to 5, and R1 to R4 are each independently selected from a hydrogen atom, an alkyl group having 1 to 5 carbon atoms, a cycloalkyl group having 3 to 6 carbon atoms, and an aryl group having 6 to 12 carbon atoms.

The adduct precursor is formed by mixing ethyl methyl sulfide or ethyl propyl ether or tetrahydrofuran with the metal compound.

The non-metal compound has at least one of group 14 elements including Si and Ge as a central element.

The non-metal compound is represented by the following Chemical Formula 11.

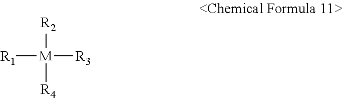

wherein M is one of group 14 elements including Si and Ge,

R1 to R4 are each independently a hydrogen atom, an alkyl group having 1 to 10 carbon atoms, an aryl group having 6 to 12 carbon atoms, an alkylamine group having 1 to 10 carbon atoms, a dialkyl amine group having 1 to 10 carbon atoms, an arylamine group having 6 to 12 carbon atoms, aralkylamine group having 7 to 13 carbon atoms, cyclic amine group having 3 to 10 carbon atoms, heterocyclic amine group having 3 to 10 carbon atoms, heteroarylamine group having 6 to 12 carbon atoms, alkylsilylamine group having 2 to 10 carbon atoms It is selected from a silylamine group, an azide group, and a halogen.

The non-metal compound is represented by the following Chemical Formula 12.

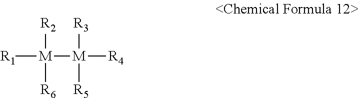

wherein M is one of group 14 elements including Si and Ge,

R1 to R6 are each independently a hydrogen atom, an alkyl group having 1 to 10 carbon atoms, an aryl group having 6 to 12 carbon atoms, an alkylamine group having 1 to 10 carbon atoms, a dialkyl amine group having 1 to 10 carbon atoms, an arylamine group having 6 to 12 carbon atoms, aralkylamine group having 7 to 13 carbon atoms, cyclic amine group having 3 to 10 carbon atoms, heterocyclic amine group having 3 to 10 carbon atoms, heteroarylamine group having 6 to 12 carbon atoms, alkylsilylamine group having 2 to 10 carbon atoms It is selected from a silylamine group, an azide group, and a halogen.

The metal/non-metal compound may exist in the form of dimer or oligomer at room temperature and pressure, and may maintain the form of dimer or oligomer even after formation of the adduct precursor.

Thereafter, a purge gas (for example, an inert gas such as Ar) is supplied to the interior of the chamber to discharge the unadsorbed surface protection material or by-products.

Then, the substrate is exposed to a reaction material supplied to the interior of the chamber, and a thin film is formed on the surface of the substrate to fill the gap features. The reaction material reacts with the adduct precursor layer to form a thin film. When the reaction material is O3, O2, or H2O gas, the thin film is a metal/non-metal oxide film. When the reaction material is ammonia (NH3), hydrazine (N2H4), nitrogen dioxide (NO2) and nitrogen (N2), the thin film is a metal/non-metal nitride film. In addition, the thin film may be a metal/non-metal sulfide or a metal/non-metal.

Thereafter, a purge gas (for example, an inert gas such as Ar) is supplied to the interior of the chamber to discharge unreacted material or by-products.

### EXAMPLE 1

In a glove box at room temperature, 10.56 g (0.139 mol) of ethyl methyl sulfide corresponding to <Chemical Formula 1> was added to a 500 ml round flask, and 5 g (0.069 mol) of trimethyl aluminum corresponding to <Chemical Formula 6> was added very slowly to obtain precursor TMA-EMS.

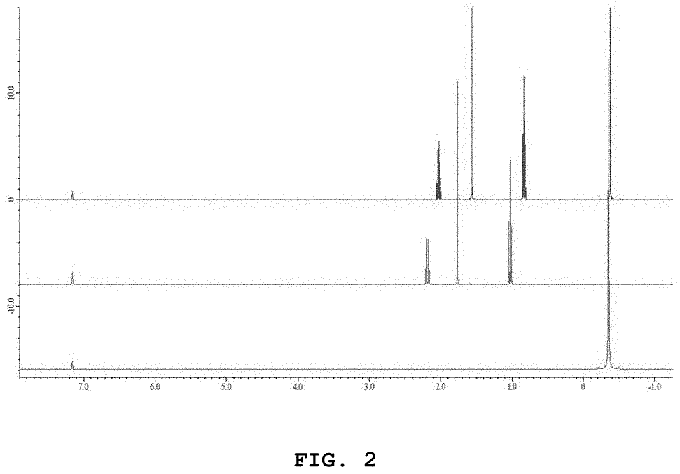

FIG. 2 is a 1H-NMR graph of the precursor TMA-EMS according to Example 1 of the present invention, and shows the NMR spectrum of Example 1/ethyl methyl sulfide/trimethyl aluminum.
Trimethyl aluminum: δ −0.36 (s)
Ethyl methyl sulfide: δ 2.19 (q), 1.76 (s), 1.20 (t)
TMA-EMS: δ −0.37 (s), δ 2.05 (q), 1.58 (s), 0.85 (t)

[symbol]

The peaks at δ =2.19 ppm, 1.76 ppm, and 1.20 ppm with chemical shifts derived from ethyl methyl sulfide shifted to 2.05 ppm, 1.58 ppm, and 0.85 ppm, respectively, without changing the shape of the peaks even after the precursor TMA-EMS was formed.

It can be seen that the peak of chemical shift δ =−0.36 ppm derived from trimethyl aluminum also moves finely without changing its shape after the formation of the precursor TMA-EMS to form a stable precursor.

### Thermal Analysis

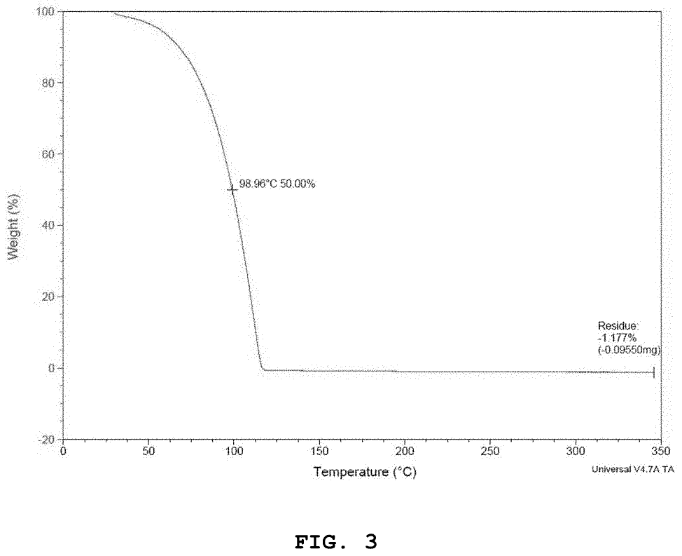

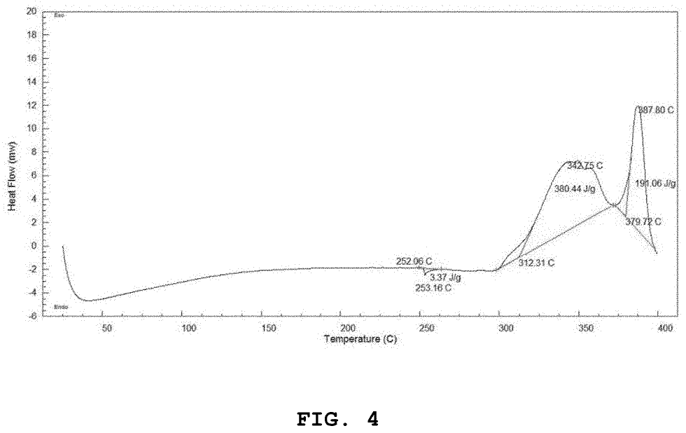

FIGS. 3 and 4 are graphs showing differential scanning calorimetry (DSC) test results and thermogravimetric analysis (TGA) test results for Example 1. A differential scanning calorimetry (DSC) test and a thermogravimetric analysis (TGA) test were performed on the TMA-EMS obtained in Example 1, and the thermal analysis test conditions for measuring the thermal decomposition temperature in each test are as follows.
Transfer gas: Argon (Ar) gas
Transfer gas flow rate: 200 ml/min
Heating profile: heating from 30° C. to 400° C. at a heating rate of 10° C./min

In the DSC test, the thermal decomposition temperature was determined as the temperature at the point where the heat flow suddenly rises when the temperature is raised in the DSC thermogram.

Referring to [Table 1] below, it can be seen that TMA-EMS has excellent vaporization characteristics and the amount of residual components is 0.1% or less, leaving no impurities in the thin film. In addition, the decomposition temperature of TMA-EMS is about 340° C., showing improved thermal stability compared to trimethylaluminum (TMA), which has a decomposition temperature of about 320° C. This can be seen as the effect of forming a stable molecule by effectively blocking the Al—Al interaction between TMAs by the organic material. In addition, it can be expected that the addition of the adduct increases the steric hindrance around the Al center, resulting in a decrease in reactivity compared to TMA before addition of the adduct.

TABLE 1

| | | | DSC Decomposition |
|---|---|---|---|
| | T½(° C.) | TGA Residue(%) | temperature(° C.) |
| TMA | 66 | <0.1 | 319 |
| X2 | 99 | <0.1 | 343 |

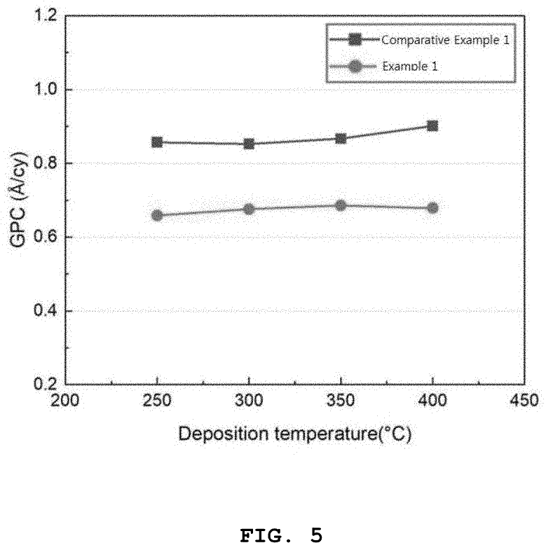

The diameter of the TMA-EMS precursor is approximately 8.6 Å, which is significantly larger than the TMA diameter of 5 Å. This not only further reduces the accessibility of the Al center and the surface —OH* of the TMA-EMS precursor, but also reduces the deposition thickness per cycle because steric hindrance acts to a greater extent when some adsorbed precursors exist on the surface. It can be confirmed through the deposition results using the TMA-EMS precursor in FIG. 5.

Similarly, the TMA-EMS precursor can form a uniform film by reducing the sticking coefficient and increasing diffusion on the surface due to reduced reactivity with the —OH* termination group on the surface, and finally uniformity and Step coverage can be improved.

### Comparative Example 1

An aluminum oxide film was formed on the silicon substrate. An aluminum oxide film was formed through an ALD process, the ALD process temperature was 250 to 400° C., and O3 gas was used as a reaction material.

The aluminum oxide film formation process through the ALD process is as follows, and the following process was performed as one cycle.
1) Ar is used as a carrier gas, the aluminum precursor TMA (Trimethylaluminium) is supplied to the reaction chamber at room temperature and the aluminum precursor is adsorbed on the substrate
2) Ar gas is supplied into the reaction chamber to discharge unadsorbed aluminum precursors or by-products
3) O3 gas is supplied to the reaction chamber to form a monolayer
4) Ar gas is supplied into the reaction chamber to discharge unreacted substances or by-products

As a result of measuring the thickness of the aluminum oxide film obtained by the above process, the thickness of the aluminum oxide film obtained for each cycle of the ALD process was about 0.9 Å/cycle at 250 to 400° C.

FIG. 5 is a graph showing GPC (Growth Per Cycle) of aluminum oxide films according to Comparative Example 1 and Example 1 of the present invention according to process temperature. As shown in FIG. 5, within the range of the substrate temperature of 250 to 400° C., the ideal ALD behavior was shown with little change in GPC according to the increase in the temperature of the substrate. Assuming that the total thickness of the dielectric film in the ZrO₂/Al₂O₃/ZrO₂ composite dielectric film of DRAM is 50 Å and the Al2O3 of Comparative Example 1 is used for about 3 cycles, the EOT of the dielectric film is 5.93 Å.

### EXAMPLE 1

An aluminum oxide film was formed on a silicon substrate using the precursor TMA-EMS according to Example 1 of the present invention. An aluminum oxide film was formed in the same manner as in Comparative Example 1, except for changing the precursor.

As a result of measuring the thickness of the aluminum oxide film obtained by the above process, the thickness of the aluminum oxide film obtained for each cycle of the ALD process was about 0.7 Å/cycle at 250 to 400° C.

In addition, as shown in FIG. 5, within the range of the substrate temperature of 250 to 400° C., the ideal ALD behavior was shown with little change in GPC according to the increase in the temperature of the substrate, and a reduction effect of about 20% compared to Comparative Example 1 is shown. Assuming that the total thickness of the dielectric film in the ZrO₂/Al₂O₃/ZrO₂ composite dielectric film of DRAM is 50 Å and the Al2O3of Example 1 is used for about 3 cycles, the EOT of the dielectric film is 5.72 Å, and a scaling down of about 4% compared to Comparative Example 1 can be secured.

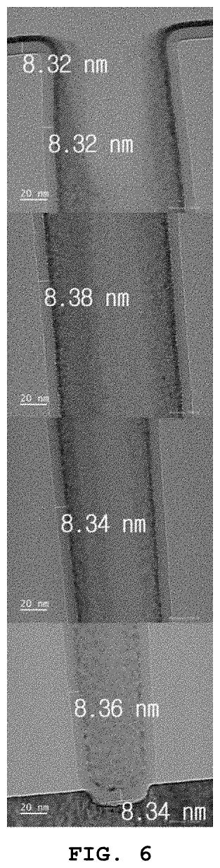

FIG. 6 is a result of confirming step coverage by depositing an aluminum oxide film according to Comparative Example 1 of the present invention on a pattern wafer at a process temperature of 400° C. (aspect ratio 20:1). As shown in FIG. 6, the thickness of the upper part obtained by repeating the process of a certain cycle was 8.32 Å and the thickness of the lower part was 8.34 Å, confirming the result of 100% step coverage.

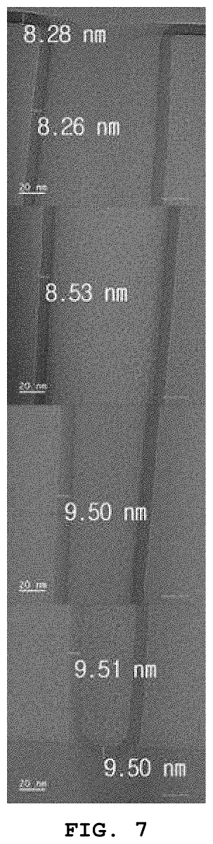

FIG. 7 is a result of confirming step coverage by depositing an aluminum oxide film according to Example 1 of the present invention on a pattern wafer at a process temperature of 400° C. (aspect ratio 20:1). As shown in FIG. 7, constant The thickness of the upper part obtained by repeating the cycle process was 8.28 Å, and the thickness of the lower part was 9.5 Å, confirming the result of step coverage of 116%, and it can be confirmed that the thickness increases by about 15% in the lower part than the upper part.

Unlike the ideal ALD behavior in a flat plate, the adduct precursor in the structure can be easily dissociated. A process temperature higher than the dissociation temperature of the adduct precursor can be interpreted as providing energy high enough to break the bond between the metal/nonmetal compound and the organic compound. Diffusion to the bottom of the structure and an increase in the number of collisions between molecules can also be interpreted as a cause of dissociation of the adduct precursor.

As a result, the dissociated organic matter has relatively high volatility and thus exists in high density in the upper part, and relatively low volatility and heavy metal/non-metal compounds may exist in high density in the lower part. The metal/non-metal compound present at a high density at the bottom is deposited at a high growth rate by recovering the original reactivity by removing the blocking effect caused by the organic matter, thereby increasing the thickness.

In conclusion, by using the adduct precursor of the present invention, it is possible to obtain a gradient adsorption characteristic in which the deposition rate increases toward the bottom. Also, when the process is repeatedly performed with a plurality of cycles, gap filing without defects can be realized even in a structure having a high aspect ratio by being filled upward from the bottom.

The present invention has been explained in detail with reference to embodiments, but other embodiments may be included. Accordingly, the technical idea and scope described in the claims below are not limited to the embodiments.

1. A method of depositing thin film, the method comprising:
supplying an adduct precursor to the inside of a chamber in which a substrate including at least one gap feature is placed so that the adduct precursor is adsorbed to the substrate;
purging the interior of the chamber; and
supplying a reaction material to the inside of the chamber so that the reaction material reacts with the adduct precursor to form the thin film and fill the gap feature,
wherein the adduct precursor is formed by mixing 1 to 5 moles of a compound represented by the following Chemical Formula 1 or following Chemical Formula 2 and 1 to 5 moles of a metal compound. 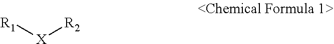
wherein X is O or S, and R1 or R2 is each independently selected from an alkyl group having 1 to 8 carbon atoms, a cycloalkyl group having 3 to 6 carbon atoms, and an aryl group having 6 to 12 carbon atoms. 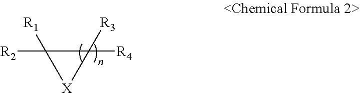
wherein X is O or S, n is 1 to 5, and R1 to R4 are each independently selected from a hydrogen atom, an alkyl group having 1 to 5 carbon atoms, a cycloalkyl group having 3 to 6 carbon atoms, and an aryl group having 6 to 12 carbon atoms.

2. The method of claim 1, wherein the adduct precursor is formed by mixing ethyl methyl sulfide or ethyl propyl ether or tetrahydrofuran with the metal compound.

3. The method of claim 1, wherein the metal compound has at least one of group 4 elements including Zr, Hf, and Ti as a central element.

4. The method of claim 1, wherein the metal compound is represented by the following Chemical Formula 3. 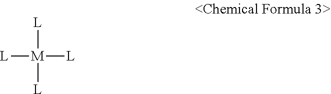
wherein M is selected from metal elements belonging to group 4 on the periodic table,
each L is the same as or different from each other, and is selected from a hydrogen atom, a linear/branched/cyclic alkyl group having 1 to 10 carbon atoms, an alkoxy group having 1 to 5 carbon atoms, an amino group having 1 to 5 carbon atoms, a dialkylamino group having 1 to 5 carbon atoms, an aryl group having 6 to 12 carbon atoms, an aralkyl group having 7 to 13 carbon atoms, and a halogen element.

5. The method of claim 1, wherein the metal compound is represented by the following Chemical Formula 4. 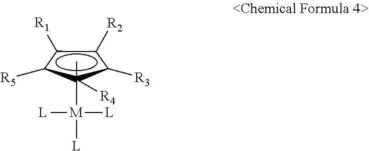
wherein M is selected from metal elements belonging to group 4 on the periodic table,
R1, R2, R3, R4, and R5 are each independently selected from a hydrogen atom, a linear/branched/cyclic alkyl group having 1 to 5 carbon atoms, an alkoxy group having 1 to 5 carbon atoms, and a phenyl group having 6 to 12 carbon atoms,
each L is the same as or different from each other, and is selected from a hydrogen atom, a linear/branched/cyclic alkyl group having 1 to 10 carbon atoms, an alkoxy group having 1 to 5 carbon atoms, an amino group having 1 to 5 carbon atoms, a dialkylamino group having 1 to 5 carbon atoms, an aryl group having 6 to 12 carbon atoms, and an aralkyl group having 7 to 13 carbon atoms,
when L is a dialkylamino group, being connected to each other to form a cyclic amine group having 3 to 10 carbon atoms.

6. The method of claim 1, wherein the metal compound has at least one of group 5 elements including Nb and Ta as a central element.

7. The method of claim 1, wherein the metal compound is represented by the following Chemical Formula 5 or the following Chemical Formula 6. 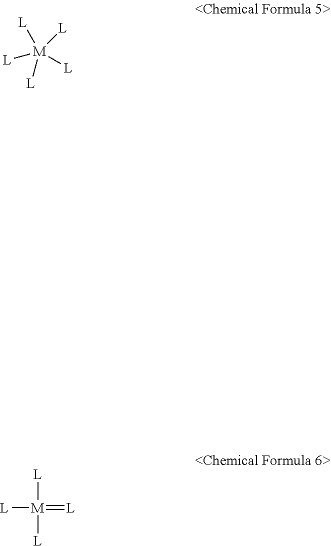
wherein M is selected from metal elements belonging to group 5 on the periodic table,
each L is the same as or different from each other, and is selected from a hydrogen atom, a linear/branched/cyclic alkyl group having 1 to 10 carbon atoms, an alkoxy group having 1 to 5 carbon atoms, an amino group having 1 to 5 carbon atoms, a dialkylamino group having 1 to 5 carbon atoms, an aryl group having 6 to 12 carbon atoms, an aralkyl group having 7 to 13 carbon atoms, and a halogen element.

8. The method of claim 1, wherein the metal compound is represented by the following Chemical Formula 7. 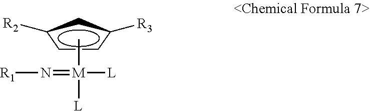
wherein M is selected from metal elements belonging to group 5 on the periodic table,
R1, R2, and R3 are each independently selected from a hydrogen atom and a linear/branched/cyclic alkyl group having 1 to 5 carbon atoms,
each L is the same as or different from each other, and is selected from a hydrogen atom, a linear/branched/cyclic alkyl group having 1 to 10 carbon atoms, an alkoxy group having 1 to 5 carbon atoms, an amino group having 1 to 5 carbon atoms, a dialkylamino group having 1 to 5 carbon atoms, an aryl group having 6 to 12 carbon atoms, an aralkyl group having 7 to 13 carbon atoms, and a halogen element.

9. The method of claim 1, wherein the metal compound has at least one of group 6 elements including W and Mo as a central element.

10. The method of claim 1, wherein the metal compound is represented by the following Chemical Formula 8 or the following Chemical Formula 9. 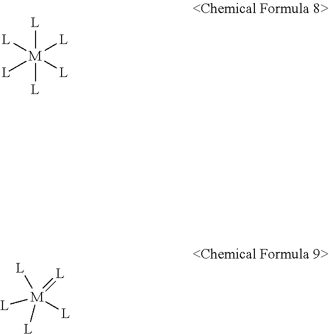
wherein M is selected from metal elements belonging to group 6 on the periodic table,
each L is the same as or different from each other, and is selected from a hydrogen atom, a linear/branched/cyclic alkyl group having 1 to 10 carbon atoms, an alkoxy group having 1 to 5 carbon atoms, an amino group having 1 to 5 carbon atoms, a dialkylamino group having 1 to 5 carbon atoms, an aryl group having 6 to 12 carbon atoms, an aralkyl group having 7 to 13 carbon atoms, and a halogen element.

11. The method of claim 1, wherein the metal compound has at least one of group 13 elements including Al as a central element.

12. The method of claim 1, wherein the metal compound is represented by the following Chemical Formula 10. 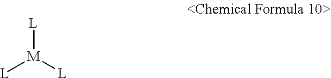
wherein M is selected from metal elements belonging to group 13 on the periodic table,
each L is the same as or different from each other, and is selected from a hydrogen atom, a linear/branched/cyclic alkyl group having 1 to 10 carbon atoms, an alkoxy group having 1 to 5 carbon atoms, an amino group having 1 to 5 carbon atoms, a dialkylamino group having 1 to 5 carbon atoms, an aryl group having 6 to 12 carbon atoms, an aralkyl group having 7 to 13 carbon atoms, and a halogen element.

13. A method of depositing thin film, the method comprising:
supplying an adduct precursor to the inside of a chamber in which a substrate including at least one gap feature is placed so that the adduct precursor is adsorbed to the substrate;
purging the interior of the chamber; and
supplying a reaction material to the inside of the chamber so that the reaction material reacts with the adduct precursor to form the thin film and fill the gap feature,
wherein the adduct precursor is formed by mixing 1 to 5 moles of a compound represented by the following Chemical Formula 1 or following Chemical Formula 2 and 1 to 5 moles of a non-metal compound. 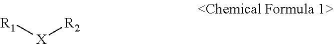
wherein X is O or S, and R1 or R2 is each independently selected from an alkyl group having 1 to 8 carbon atoms, a cycloalkyl group having 3 to 6 carbon atoms, and an aryl group having 6 to 12 carbon atoms. 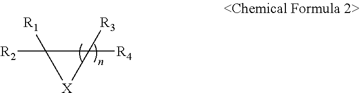
wherein X is O or S, n is 1 to 5, and R1 to R4 are each independently selected from a hydrogen atom, an alkyl group having 1 to 5 carbon atoms, a cycloalkyl group having 3 to 6 carbon atoms, and an aryl group having 6 to 12 carbon atoms.

14. The method of claim 13, wherein the adduct precursor is formed by mixing ethyl methyl sulfide or ethyl propyl ether or tetrahydrofuran with the metal compound.

15. The method of claim 13, wherein the non-metal compound has at least one of group 14 elements including Si and Ge as a central element.

16. The method of claim 15, wherein the non-metal compound is represented by the following Chemical Formula 11. 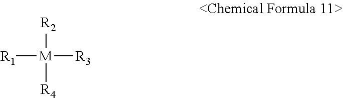
wherein M is one of group 14 elements including Si and Ge,
R1 to R4 are each independently a hydrogen atom, an alkyl group having 1 to 10 carbon atoms, an aryl group having 6 to 12 carbon atoms, an alkylamine group having 1 to 10 carbon atoms, a dialkyl amine group having 1 to 10 carbon atoms, an arylamine group having 6 to 12 carbon atoms, aralkylamine group having 7 to 13 carbon atoms, cyclic amine group having 3 to 10 carbon atoms, heterocyclic amine group having 3 to 10 carbon atoms, heteroarylamine group having 6 to 12 carbon atoms, alkylsilylamine group having 2 to 10 carbon atoms It is selected from a silylamine group, an azide group, and a halogen.

17. The method of claim 15, wherein the non-metal compound is represented by the following Chemical Formula 12. 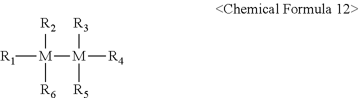
wherein M is one of group 14 elements including Si and Ge,
R1 to R6 are each independently a hydrogen atom, an alkyl group having 1 to 10 carbon atoms, an aryl group having 6 to 12 carbon atoms, an alkylamine group having 1 to 10 carbon atoms, a dialkyl amine group having 1 to 10 carbon atoms, an arylamine group having 6 to 12 carbon atoms, aralkylamine group having 7 to 13 carbon atoms, cyclic amine group having 3 to 10 carbon atoms, heterocyclic amine group having 3 to 10 carbon atoms, heteroarylamine group having 6 to 12 carbon atoms, alkylsilylamine group having 2 to 10 carbon atoms It is selected from a silylamine group, an azide group, and a halogen.

18. The method of claim 1, wherein the thin film is any one of metal oxide, metal nitride, metal sulfide, or metal.

19. The method of claim 13, wherein the thin film is any one of non-metal oxide, non-metal nitride, non-metal sulfide, or non-metal.

20. The method of claim 1, wherein the method proceeds at a dissociation temperature or higher of the adduct precursor.

21. The method of claim 1, wherein the method proceeds at 50 to 700° C.

22. A method of manufacturing a volatile memory device, the method comprising the method of forming a thin film according to any one of claim 1.

23. A method of manufacturing a non-volatile memory device, the method comprising the method of forming a thin film according to any one of claim 1.

24. The method of claim 13, wherein the method proceeds at a dissociation temperature or higher of the adduct precursor.

25. The method of claim 13, wherein the method proceeds at 50 to 700° C.

26. A method of manufacturing a volatile memory device, the method comprising the method of forming a thin film according to any one of claim 13.

27. A method of manufacturing a non-volatile memory device, the method comprising the method of forming a thin film according to any one of claim 13.
